(19) United States
(12) Patent Application Publication
(10) Pub. No.: US 2014/0184808 A1
(43) Pub. Date: Jul. 3, 2014

(54) Photoelectric Conversion Device and Imaging Apparatus Having the Photoelectric Conversion Device

(71) Applicant: CANON KABUSHIKI KAISHA, Tokyo (JP)

(72) Inventors: Tatsuya RYOKI, Kawasaki-shi (JP); Kiyofumi SAKAGUCHI, Miura-gun (JP); Noriyuki KAIFU, Hachioji-shi (JP)

(21) Appl. No.: 14/108,846

(22) Filed: Dec. 17, 2013

(30) Foreign Application Priority Data
Dec. 20, 2012 (JP) 2012-278323
Nov. 25, 2013 (JP) 2013-243270

(51) Int. Cl. H04N 5/33; H04N 5/378

(52) U.S. Cl. CPC H04N 5/332; H04N 5/378
USPC 348/164

(57) ABSTRACT

A photoelectric conversion device includes visible-light filters, infrared light filters, pixels arrayed in a row direction and a column direction, and wiring layers disposed between the pixels and visible-light filters and infrared light filters. The pixels include first pixels disposed corresponding to the visible-light filters, and second pixels disposed corresponding to the infrared light filters. The shape and size of the first pixels and second pixels is the same in planar view. The second pixels are disposed between adjacent pixels of the first pixels in the row direction, column direction, and diagonal directions. At least one wiring layer of the wiring layers defines apertures corresponding to photoelectric conversion regions at the first pixels and second pixels. Apertures corresponding to photoelectric conversion regions of first pixels and apertures corresponding to photoelectric conversion regions of second pixels are of the same shape and size in planar view.

### BACKGROUND OF THE INVENTION

1. Field of the Invention

The present invention relates to a photoelectric conversion device capable of acquiring signals based on visible light and infrared light.

2. Description of the Related Art

Imaging apparatuses including photoelectric conversion devices which can acquire visible-light images and infrared light images are used in shooting pictures with surveillance cameras and the like, on-board applications, medical applications, and so forth. Japanese Patent Laid-Open No. 2006-352466 discloses a photoelectric conversion device including pixels having visible-light filters to detect color image information of an object, and pixels having infrared light filters. Japanese Patent Laid-Open No. 2006-352466 also discloses in FIG. 4 thereof a photoelectric conversion device where the size of pixels where the infrared light filters have been provided are larger than the size of pixels where the visible-light filters have been provided to raise the sensitivity as to infrared light.

Generally, photoelectric conversion devices have apertures, defining regions through which incident light to the pixels can pass, formed of wiring and the like. These apertures prevent colors from mixing among pixels, which can occur due to obliquely incident light to the pixels. On the other hand, there are cases where the apertures form regions in the pixels where light does not readily reach. Particularly, the amount of incident light decreases at the periphery portion of the photoelectric conversion device where there is a greater amount of obliquely incident light due to shadows formed by the apertures. Accordingly, detected light signals are corrected to make up for the reduction in the amount of incident light.

The photoelectric conversion device disclosed in FIG. 4 of Japanese Patent Laid-Open No. 2006-352466 is arranged such that the pixels where visible-light filters are disposed and the pixels where infrared light filters are disposed have different sizes and shapes. This means that apertures formed corresponding to the shapes of the pixels where visible-light filters are disposed and the pixels where infrared light filters are disposed, will have different aperture shapes. This further means that the shapes of shadows cast by the apertures formed above the pixels where visible-light filters are disposed and the pixels where infrared light filters are disposed will be different. Consequently, different light signal correction needs to be performed for pixels where visible-light filters are disposed and for the pixels where infrared light filters are disposed, so correction value properties have to be obtained for each of the pixels.

### SUMMARY OF THE INVENTION

It has been found desirable to provide a photoelectric conversion device capable of similar signal correction on infrared light pixels and visible-light pixels, while increasing sensitivity to infrared light.

According to one aspect of the present invention, a photoelectric conversion device includes a plurality of visible-light filters, a plurality of infrared light filters, a plurality of pixels arrayed in a row direction and a column direction, and a plurality of wiring layers disposed between the plurality of pixels and the visible-light filters and infrared light filters. The plurality of pixels include first pixels disposed corresponding to the visible light filters, and second pixels disposed corresponding to the infrared light filters. The shape and size of the first pixels and the second pixels is the same in planar view. The second pixels are disposed between adjacent pixels of the plurality of first pixels in the row direction, the column direction, and diagonal directions. At least one wiring layer of the plurality of wiring layers defines apertures corresponding to photoelectric conversion regions at the first pixels and the second pixels. Apertures corresponding to the photoelectric conversion regions of the first pixels and apertures corresponding to the photoelectric conversion regions of the second pixels are of the same shape and size in planar view.

According to another aspect of the present invention, a photoelectric conversion device includes a plurality of visible-light filters, a plurality of white light filters, a plurality of pixels arrayed in a row direction and a column direction, and a plurality of wiring layers disposed between the plurality of pixels and the visible-light filters and white light filters. The plurality of pixels include first pixels disposed corresponding to the visible light filters, and second pixels disposed corresponding to the white light filters. The size and shape of the first pixels and the second pixels is the same. The second pixels are disposed between adjacent pixels of the plurality of first pixels in the row direction, the column direction, and diagonal directions. Apertures are formed above the first pixels and the second pixels by the plurality of wiring layers. The shape of the apertures are the same above the first pixels and above the second pixels.

### BRIEF DESCRIPTION OF THE DRAWINGS

FIG. 1 is a schematic diagram of a photoelectric conversion device according to a first embodiment.

FIG. 2 is a plan schematic diagram for describing the first embodiment.

FIG. 3 is a top view of a photoelectric conversion device according to the first embodiment.

FIG. 4A is a cross-sectional view taken along line IVA-IVA in FIG. 3.

FIG. 4B is a cross-sectional view taken along line IVB-IVB in FIG. 3.

FIG. 5 is a top view of color filters of the photoelectric conversion device according to the first embodiment.

FIG. 6 is a cross-sectional diagram of pixels of the photoelectric conversion device according to the first embodiment.

FIG. 7 is a cross-sectional diagram of pixels of the photoelectric conversion device according to the first embodiment.

FIG. 8 is a circuit diagram of pixels of the photoelectric conversion device according to the first embodiment.

FIG. 9A is a diagram illustrating operation of the photoelectric conversion device according to the first embodiment.

FIG. 9B is a diagram illustrating operation of the photoelectric conversion device according to the first embodiment.

FIG. 10A is a plan schematic diagram for describing an example of a second embodiment.

FIG. 10B is a plan schematic diagram for describing another example of the second embodiment.

FIG. 11A is a plan schematic diagram for describing a third embodiment.

FIG. 11B is a top view of color filters, for describing the third embodiment.

FIG. 12A is a plan schematic diagram for describing a fourth embodiment.

FIG. 12B is a top view of color filters, for describing the fourth embodiment.

FIG. 13 is a top view of color filters, for describing a fifth embodiment.

FIG. 14 is a cross-sectional diagram of pixels of the photoelectric conversion device according to the fifth embodiment.

FIG. 15 is a diagram for describing signal correction.

FIG. 16 is a diagram for describing signal correction.

FIG. 17 is a diagram for describing signal correction.

FIG. 18 is a schematic diagram for describing an imaging apparatus.

FIG. 19 is a schematic diagram for describing spectral transmittance of filters.

### DESCRIPTION OF THE EMBODIMENTS

In the following description, pixels provided with visible-light filters will be referred to as “visible-light pixels”, and pixels provided with infrared (IR) filters will be referred to as “IR pixels”. For example, if a visible-light filter is a primary color filter, the visible-light filter will have one of a red filter (R filter) which primarily transmits red light, a green filter (G filter) which primarily transmits green light, and a blue filter (B filter) which primarily transmits blue light. Also hereinafter, pixels provided with R filters will be referred to as “R pixels”, pixels provided with G filters will be referred to as “G pixels”, and pixels provided with B filters will be referred to as “B pixels”. Also, R pixels, G pixels, and B pixels, which detect the visible light range, may also be collectively referred to as “visible-light pixels”.

The following description of an embodiment will be made regarding an arrangement where one filter is provided per pixel. We will also say that the pixel shape and filter shape are all the same in plan view, and that the areas of the multiple pixels provided in a pixel portion are all the same. Each pixel has at least one photoelectric conversion element, which is a photodiode in the present embodiment.

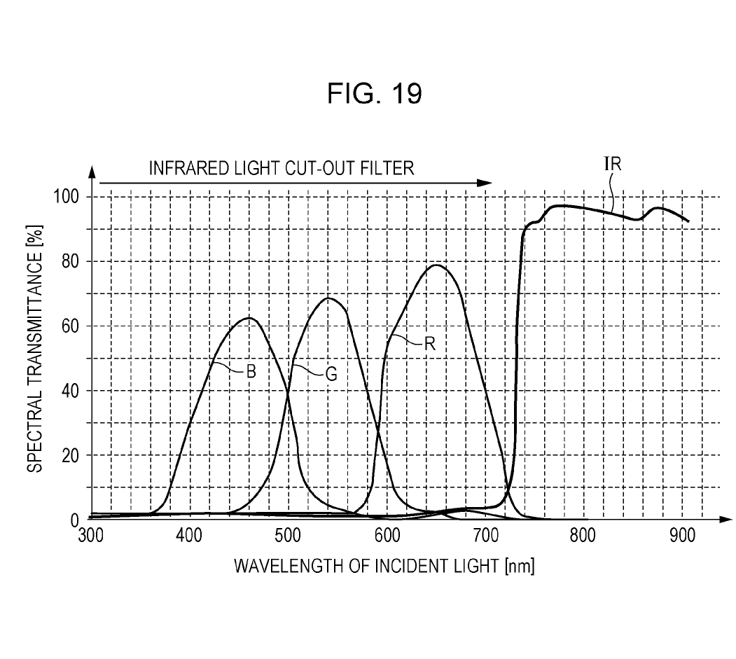

The spectral transmittance of filters in the embodiments will be described here. FIG. 19 is a graph illustrating wavelength along the horizontal axis (in units of nm) and spectral transmittance along the vertical axis (in units of %). First, the wavelength range of visible light is generally a range between 400 nm and 700 nm. The wavelength range of infrared light is 750 nm to 1 mm. Now, the spectral transmittance of the IR filter is 50% or more in a wavelength range of at least 700 nm or longer, and less than 50% at wavelengths less than 700 nm. That is to say, the IR filter is a filter to primarily transmit infrared light. As can be seen from FIG. 19, the solid line IR indicates that the spectral transmittance of the IR filter reaches above 90% spectral transmittance around 740 nm, but does not exceed 50% at lower than 700 nm. On the other hand, the spectral transmittances of the visible-light filters exceed 50% in the wavelength range lower than 700 nm. That is to say, the visible-light filters are filters to primarily transmit visible light. It is sufficient for the visible-light filters to transmit light which is in the visible-light range lower than the wavelength range of infrared light, and accordingly transmits light of wavelengths shorter than 700 nm, for example. The solid lines R, G, and B in FIG. 19 indicate that the spectral transmittance of each of the visible-light filters exceeds 50% at particular respective wavelengths lower than 700 nm. For example, the peak of spectral transmittance of the R filter is approximately 650 nm, the peak of spectral transmittance of the G filter is approximately 550 nm, and the peak of spectral transmittance of the B filter is approximately 450 nm. While the visible-light filters partially transmit light of the infrared light range in some cases, the visible-light filters may be designed so that light of the infrared light range is not transmitted. That is to say, the visible-light filters may be designed such that light of 700 nm or longer, for example, is not transmitted, so as to eliminate effects of infrared light. The visible-light filters may also include infrared light cut-off filters to cut out light of 700 nm or longer, for example. The example illustrated in FIG. 19 exemplifies the range of light transmitting an IR cut-off filter. The filters may be formed of organic or inorganic materials. Further, the term “non-transparent” as used hereinafter is not restricted to a material which is 100% non-transmitting.

Embodiments will now be described in detail with reference to the drawings.

### First Embodiment

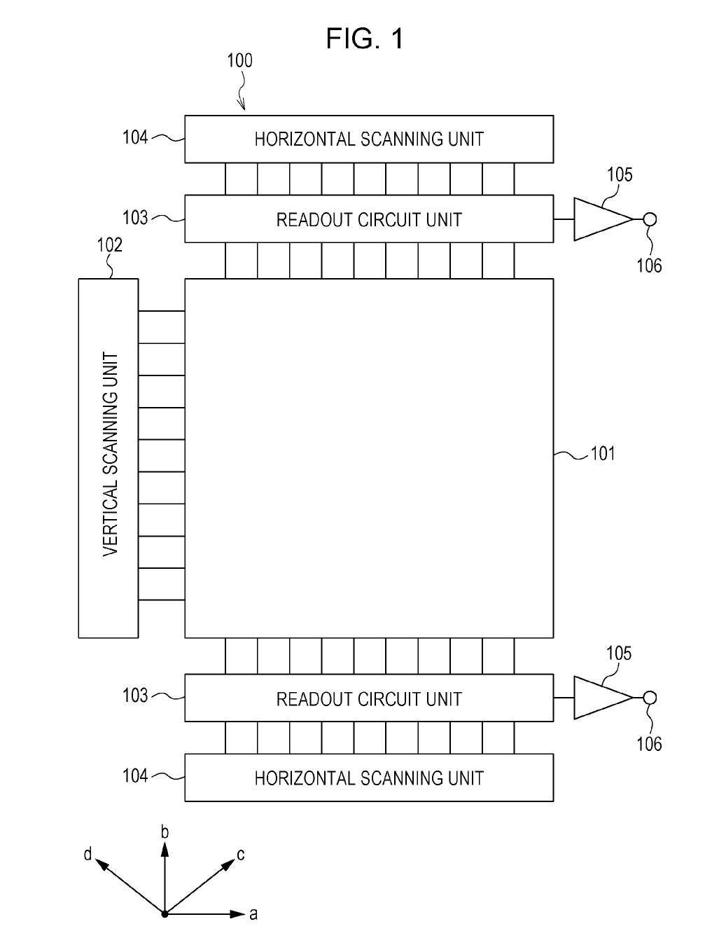

A photoelectric conversion device according to a first embodiment will be described with reference to FIGS. 1 through 5. First, an overview of the photoelectric conversion device according to the present embodiment will be described with reference to the schematic diagram in FIG. 1.

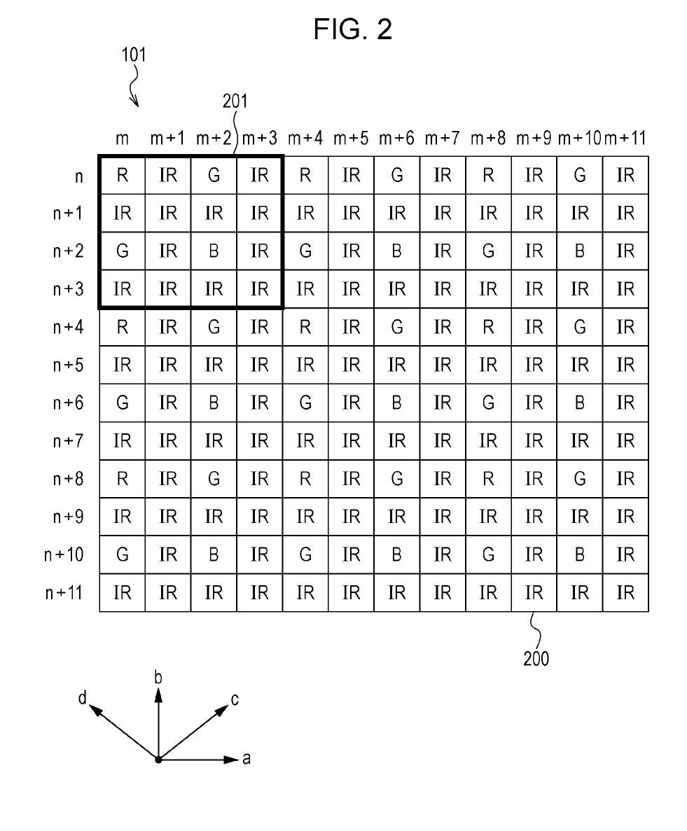

A photoelectric conversion device 100 illustrated in FIG. 1 includes a pixel unit 101, a vertical scanning unit 102, read-out circuit units 103, horizontal scanning units 104, output units 105, and terminals 106. The pixel unit 101 includes multiple pixels which output signals according to charges generated corresponding to incident light. The multiple pixels are arrayed in a matrix, for example. The vertical scanning unit 102 is a shift register, for example, which supplies control signals to read out signals from the multiple pixels. The read-out circuit units 103 are circuits which subject the signals from the multiple pixels to processing such as addition or amplification. The horizontal scanning units 104 are shift registers, for example, which control transmission of signals from the read-out circuit units 103 to the output units 105. The output units 105 are parts which output signals to the terminals 106 for external connection. The output units 105 are difference amplifiers, for example. In FIGS. 1 and 2, a first direction a is the horizontal direction which is also the row direction, and a second direction b is the vertical direction which is also the column direction. The first direction a and second direction b intersect at right angles. A third direction c is at an angle 45 degrees as to the first direction a, and a fourth direction d intersects the third direction c at right angles.

The pixel array of the pixel unit 101, i.e., the filter array, will be described with reference to FIG. 2. FIG. 2 is a plan view schematically illustrating a part of the pixel unit 101. FIG. 2 illustrates 144 pixels in the pixel unit 101, 12 pixels in the first direction a by 12 pixels in the second direction b. m through m+11 are pixel column numbers, and n through n+11 are pixel row numbers. Note that m and n are integers, and that in the following description, a given pixel, such as a pixel at column m+1 and row n+1, will be written as pixel (m+1, n+1). Also, in FIG. 2 symbol R denotes red filters, G denotes green filters, B denotes blue filters, and IR denotes IR filters. In other words, FIG. 2 can be said to be a schematic diagram of a filter array. Also, FIG. 2 can be said to illustrate the array face of the filter array where visible-light filters and infrared light filters are arrayed.

The outer edges of the pixels according to the present embodiment form a square shape in the array face, and are arrayed in matrix fashion, as illustrated in FIG. 2. R filters, G filters, B filters, and IR filters are disposed on the pixels arrayed in this way. Multiple IR filters are disposed so as to surround each of the R filters, G filters, and B filters, which as visible-light filters. The visible-light filters are adjacent to IR filters in the row direction, column direction, and diagonal directions, with an IR filter disposed between visible-light filters in each direction.

For example, four IR pixels are disposed at positions closest to B pixel (m+2, n+2). The four pixels are IR pixel (m+2, n+1), IR pixel (m+2, n+3), IR pixel (m+1, n+2), and IR pixel (m+3, n+2). The term closest position means a position at a distance of one pixel, i.e., at a single pitch. Distance between pixels can be decided using the center of gravity of the pixels. Further, all pixels adjacent to the B pixel (m+2, n+2) in the diagonal directions are also IR pixels. Specifically, the pixels disposed at (m+1, n+1), (m+3, n+1), (m+1, n+3), and (m+3, n+3) adjacent to the corners of the B pixels (m+2, n+2) are all IR pixels. In the same way with R pixels and G pixels besides the B pixels, four IR pixels are disposed at positions closest to the R pixels and G pixels, as well as all four pixels adjacent in the diagonal directions being IR pixels.

This arrangement where visible-light pixels are surrounded by IR pixels, and the size and shape of the visible-light pixels and IR pixels are the same, enables similar signal correction on infrared light pixels and visible-light pixels, while increasing sensitivity to IR light. On the other hand, the related art has had a configuration where the shapes of the visible-light pixels and the IR pixels differ to detect IR light at a high level of sensitivity. Accordingly, the shapes of apertures formed corresponding to this also differ, necessitating correction of visible-light pixels and IR pixels using different properties. However, according to the present embodiment, the visible-light pixels and IR pixels have the same shape and size, so the same signal processing can be performed on both the visible-light pixels and IR pixels. Correction to compensate for reduction in incident light to the pixels, which occurs due to wiring defining the apertures and positions corresponding to the photoelectric conversion regions, will be described later.

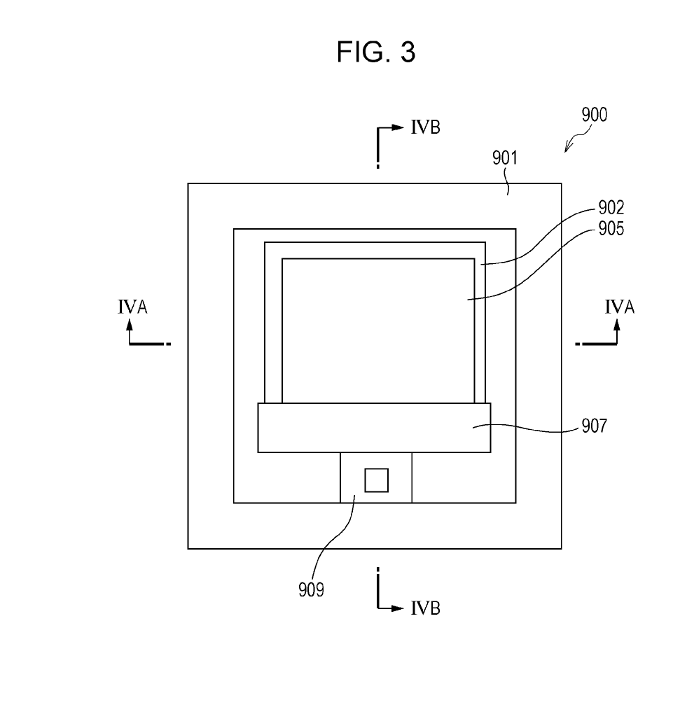

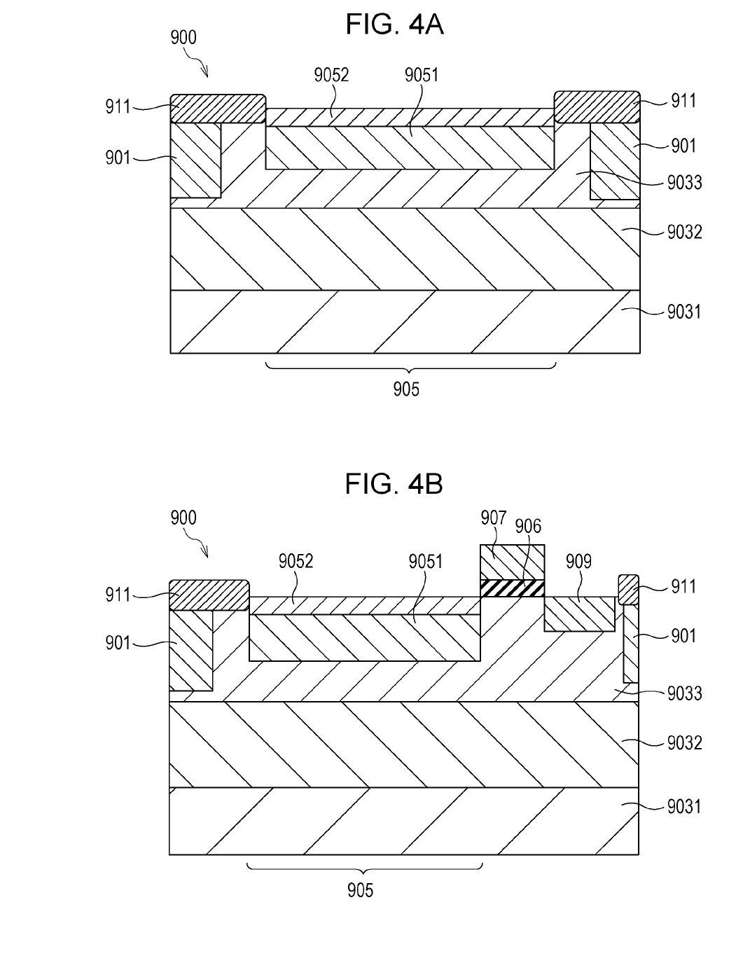

Next, detailed structure of pixels according to the present embodiment will be made with reference to FIGS. 3 through 4B. FIG. 3 is a plan view illustrating a region above a semiconductor substrate corresponding to one pixel 900.

Formed in a pixel 900 is a high-concentration p-type impurity region 901 to prevent movement of signal charge to and from adjacent pixels. An active region 902 is formed surrounded by the p-type impurity region 901. A photoelectric conversion region (hereinafter also referred to as “PD region”) 905 is formed in the active region 902. A gate electrode 907 is disposed adjacent to the PD region 905, so that charge generated at the PD region 905 is transferred to a floating diffusion region (hereinafter also referred to as “FD region”) 909 by the gate electrode 907. Note that an insulating separative film defining the active region 902 is omitted from illustration in FIG. 3. PD region 905 may be formed in such a way that the boundaries of PD region 905 are consistent with the boundaries of the active region 902.

Next, FIG. 4A illustrates a cross-sectional view taken along line IVA-IVA in FIG. 3. The PD region 905 includes a charge storage region 9051, a p-type impurity region 9052 disposed above the charge storage region 9051 on the substrate, and a p-type impurity region 9033. The semiconductor substrate is formed by an n-type epitaxial layer 9032 having been formed on the front face of an n-type semiconductor substrate 9031, and the p-type impurity region 9033 further formed upon the n-type epitaxial layer 9032.

Next, FIG. 4B illustrates a cross-sectional view taken along line IVB-IVB in FIG. 3. The charge storage region 9051 and FD region 909 are formed separated from each other, and a gate insulating film 906 and the gate electrode 907 are disposed on the p-type impurity region 9033 between the charge storage region 9051 and the FD region 909.

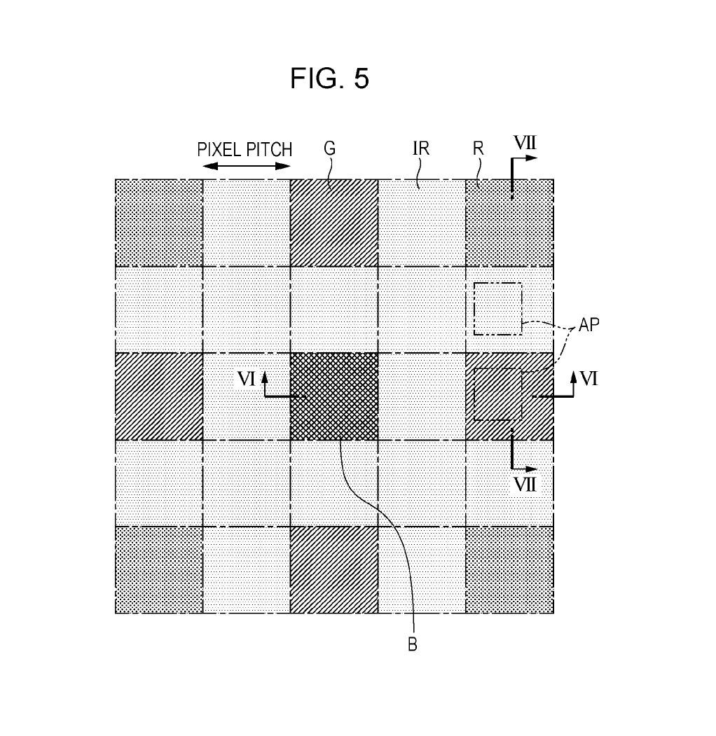

An aperture disposed corresponding to each PD region 905 will be described with reference to FIG. 5. FIG. 5 illustrates a part of the pixel unit 101 in plan view. Each region surrounded by one-dot dashed lines is one pixel, serving as the smallest unit of repetition making up the imaging region. Filters configured of organic material are disposed above the pixels. One of an R filter, G filter, B filter, and IR filter, is disposed above each pixel. Also, an aperture AP defined by wiring, which is omitted from illustration, is provided above each pixel. A microlens, also omitted from illustration, is provided above each filter. Light condensed by the microlens passes through the aperture AP and inters the PD region.

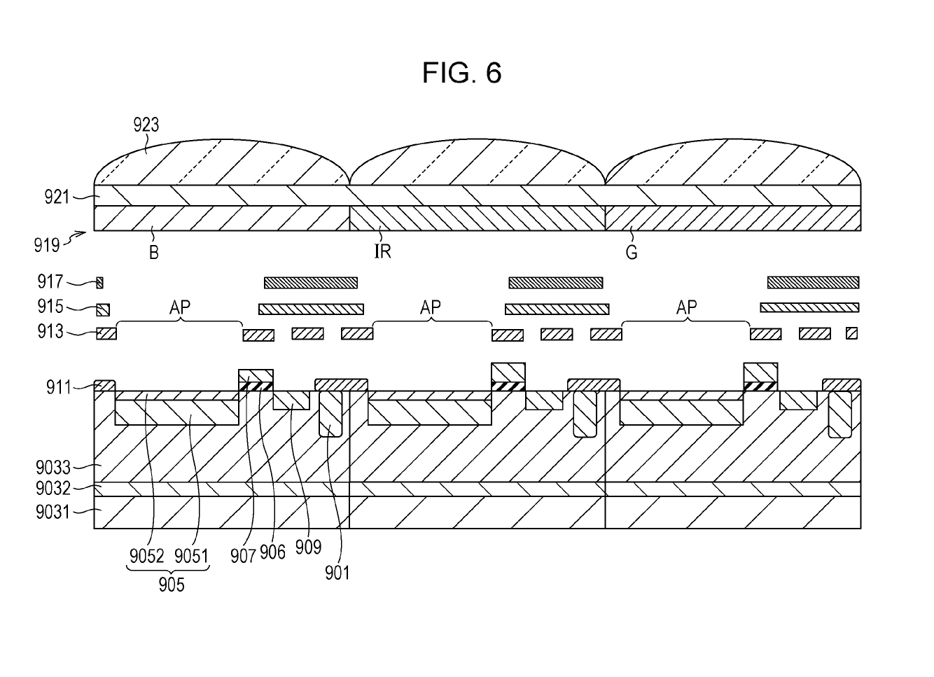

FIG. 6 is a cross-sectional view taken along VI-VI in FIG. 5. A first wiring layer 913, second wiring layer 915, and a third wiring layer 917 are formed above the semiconductor substrate. The wiring layers 913 through 917 each have a predetermined wiring pattern. The wiring included in each wiring layer is disposed such that input of light to the PD region 905 is not excessively impeded. Of the wiring in each layer disposed above the PD region 905, the distance between wiring included in the first wiring layer 913 is the narrowest in the X direction in the present embodiment. That is to say, the width of the aperture AP in the X direction is defined by the wiring included in the first wiring layer 913.

An unshown inter-layer insulating film is provided above the third wiring layer 917, and thereabove are provided a color filter layer 919, a smoothing layer 921, and a microlens 923. The color filter layer 919 is made up of multiple color filters disposed corresponding to each PD region 905. Three types of filters, which are a B filter, IR filter, and G filter, are disposed as to respective PD regions 905 in FIG. 6. The color filters are formed so as to be in contact with each other. The microlenses 923 are formed so as to be partially in contact with each other.

Each color filter included in the color filter layer 919 and microlenses 923 are disposed such that the centers thereof match the centers of the charge storage regions 9051. This configuration enables light condensed by the microlens 923 to be input to the PD region 905 without fail, and converted into electric signals. Alternatively, an arrangement may be made where the centers of the color filters and the microlenses 923 are offset from the centers of the charge storage regions 9051 toward the perimeter of the imaging region. This configuration enables sensitivity regarding oblique incident light to be improved.

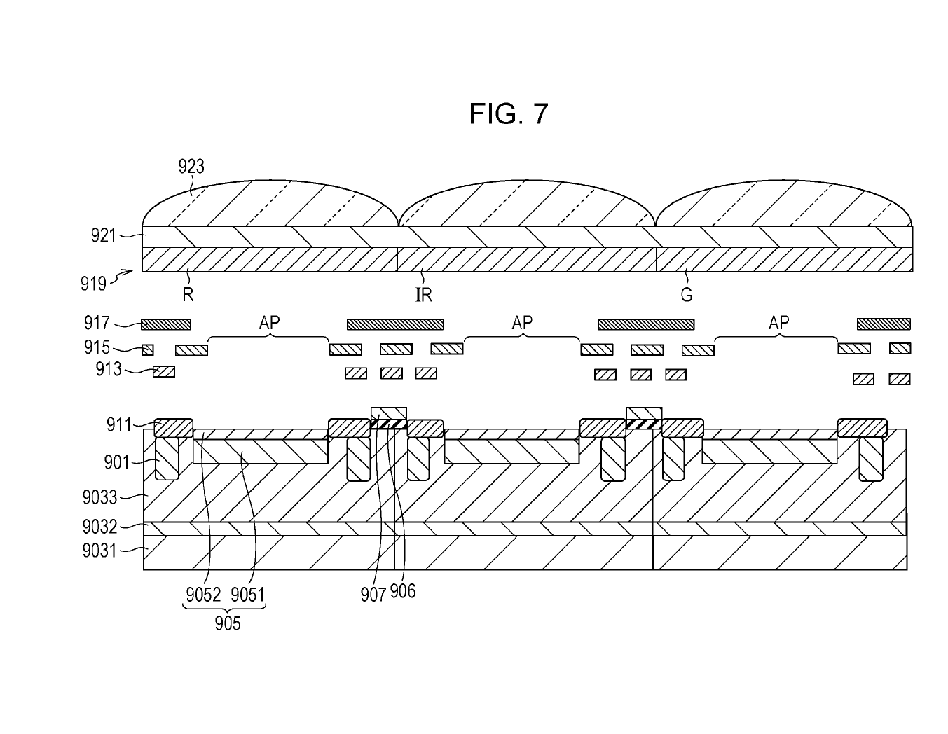

FIG. 7 is a cross-sectional view taken along VII-VII in FIG. 5. Of the wiring in each wiring layer disposed above the PD region 905, the distance between wiring included in the second wiring layer 915 is the narrowest in the Y direction in the present embodiment. That is to say, the width of the aperture AP in the Y direction is defined by the wiring included in the second wiring layer 915. Three types of filters, which are an R filter, IR filter, and G filter, are disposed as to respective PD regions 905 in the cross-sectional view in FIG. 7. The color filters are formed so as to be in contact with each other. The microlenses 923 are formed so as to be partially in contact with each other, in the same way as with the cross-sectional view in FIG. 6.

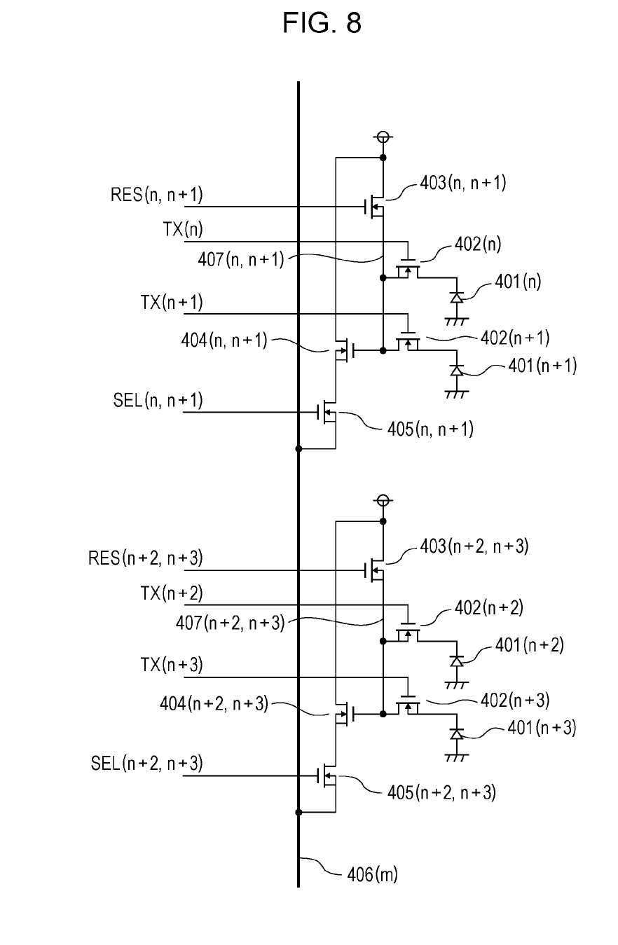

Next, a specific circuit configuration which the pixel unit 101 according to the present embodiment has will be described with reference to FIG. 8. FIG. 8 illustrates an equivalency circuit of pixels provided to the pixel unit 101. FIG. 8 illustrates, of pixels arrayed in matrix fashion, four rows worth of pixel circuits from row n to row n+3 (where n is an integer) disposed in column m (where m is an integer). In the following description, this pixel equivalency circuit in FIG. 8 corresponds to, for example, pixels 200 from row n through row n+3 of column m in FIG. 2. The circuit in FIG. 8 is repetitive throughout the pixel unit 101 in FIG. 2, for example.

Two photoelectric conversion devices 401 adjacent in the second direction b share a reset transistor 403, an amplification transistor 404, and a select transistor 405, as illustrated in FIG. 8. That is to say, two pixels are the smallest unit of repetition of the pixel circuit as illustrated in FIG. 8. Now, 401 (n) in FIG. 8 means photoelectric conversion device 401 at row n, and 403 (n, n+1) means reset transistor 403 corresponding to row n and row n+1. In the following description, other symbols with integers n through n+3 have similar meanings.

Basic operations of the pixel circuit at row n and row n+1 will be described with reference to FIG. 8. A charge generated at the photoelectric conversion device 401 (n) is transferred to the FD region by a transfer transistor 402 (n). A charge generated at the photoelectric conversion device 401 (n+1) is transferred to the FD region by a transfer transistor 402 (n+1). The FD region makes up a gate electrode of amplification transistor 404 (n, n+1) and a floating node (hereinafter “FD node”) 407 (n, n+1). The amplification transistor 404 (n, n+1) outputs a signal based on the potential of the FD node 407 (n, n+1) to a signal line 406 (m). The select transistor 405 (n, n+1) control electric conduction between the amplification transistor 404 (n, n+1) and the signal line 406 (m). The reset transistor 403 (n, n+1) resets the potential of the FD node 407 (n, n+1). The operations of the transfer transistor 402 (n), the transfer transistor 402 (n+1), the reset transistor 403 (n, n+1), and the select transistor 405 (n, n+1), are controlled by control signals from the vertical scanning unit 102 illustrated in FIG. 1. Control signals include a signal TX (n) to the transfer transistor 402 (n) and a signal TX (n+1) to the transfer transistor 402 (n+1). Further, the control signals include a signal RES (n, n+1) to the reset transistor 403 (n, n+1), and a signal SEL (n, n+1) to the select transistor 405 (n, n+1).

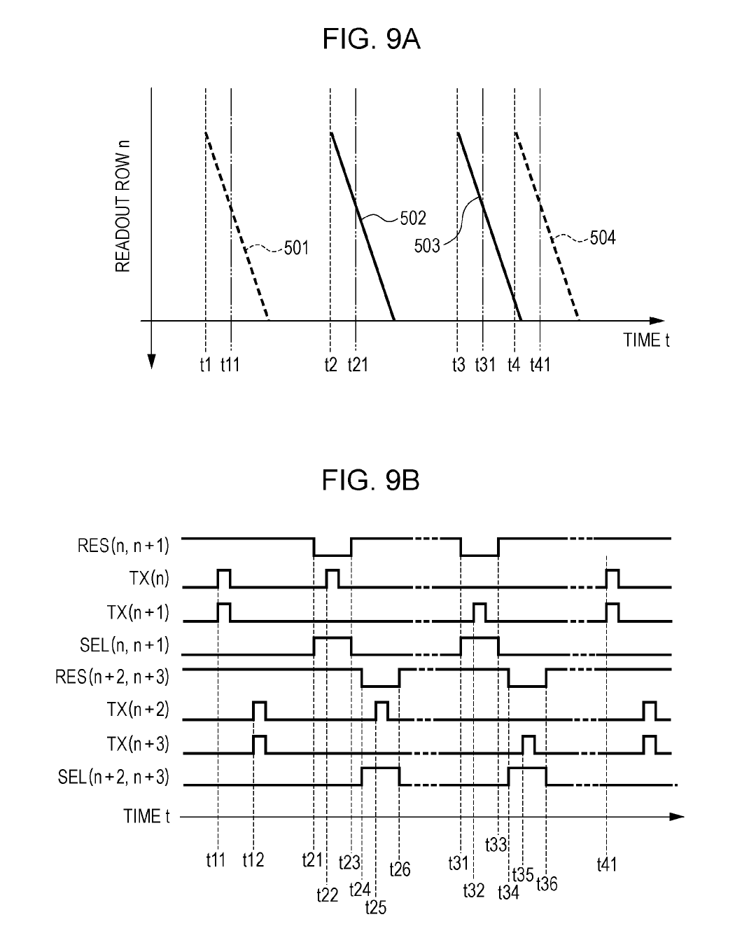

Next, the signal readout method of the photoelectric conversion device according to the present embodiment will be described with reference to FIGS. 9A and 9B. There are at least two methods for the signal readout method of the photoelectric conversion device according to the present embodiment. One method is to read out signals of visible-light pixels as a first frame, and subsequently read out signals of IR pixels as a second frame. Another method is to read out signals of visible-light pixels and signals of IR pixels at the same time. In other words one method is a method of reading out visible-light image signals and IR image signals as separate frames, and another method is to read out visible-light image signals and infrared light image signals as a single frame. The method where visible-light pixel signals and IR pixel signals are read out at the same time is the same as the method usually employed in the related art, so description thereof will be omitted.

The first readout method mentioned above will be described with reference to the timing charts in FIGS. 9A and 9B. FIG. 9A illustrates overall operation timings of the pixel unit 101, and FIG. 9B illustrates specific operation timings at the pixel circuit illustrated in FIG. 8.

The vertical axis in FIG. 9A represents readout row n, and the horizontal axis represents point-in-time t. The arrow on the vertical axis represents the direction of scanning, indicating that scanning is performed from row 1 to row n of the pixel unit 101. First, at point-in-time t1, a scan 501 starts, and reset is performed. At point-in-time t2, a scan 502 starts, and readout of signals of visible-light pixels is performed. This operation reads out image signals of visible light as a first frame. Next, at point-in-time t3, a scan 503 starts, and readout of signals of infrared light pixels is performed. This operation yields image signals of infrared light as a second frame. At point-in-time t4, a scan 504 starts, and reset is performed. In the case of a moving image, scans 502, 503, and 504 are repeatedly performed after this scan 504. This series of operations will be described in detail with reference to FIG. 9B.

FIG. 9B illustrates the value (level) of control signals of the pixel circuit illustrated in FIG. 8 at each point-in-time t. We will say that when the value of each control signal is at high level, the transistor conducts (ON), and when the value of each control signal is at low level, the transistor does not conduct (OFF). For example, in a case where the transistor is a p-type MOS transistor, high level means a lower voltage than low level. Hereinafter, description will be made regarding the pixels at row n through row n+3 in FIG. 2 (the pixels of row n through row n+3 in column m in FIG. 2). Description of similar operations will be omitted from the following description as appropriate.

First, at point-in-time t11, in a state where signal RES (n, n+1) is at high level, signal TX (n) and signal TX (n+1) go to high level. At this time, in a state with the reset transistor 403 (n, n+1) in FIG. 8 on, the transfer transistor 402 (n) and transfer transistor 402 (n+1) turn on. This operation resets the photoelectric conversion device 401 (n) and photoelectric conversion device 401 (n+1). Thereafter, the signal TX (n) and signal TX (n+1) go to low level, and storing of signal charges at the photoelectric conversion device 401 (n) and photoelectric conversion device 401 (n+1) starts. Also, the FD node 407 (n, n+1) is in a reset state at this time.

At point-in-time t12, reset is performed at row n+2 and row n+3, in the same way as with the pixels at row n and row n+1 at point-in-time t11. In a state where the signal RES (n+2, n+3) is at high level, signal TX (n+2) and signal TX (n+3) go to high level. This operation resets the photoelectric conversion device 401 (n+2) and photoelectric conversion device 401 (n+3). Subsequently, the signal TX (n+2) and signal TX (n+3) go to low level, and storing of signal charges at the photoelectric conversion device 401 (n+2) and photoelectric conversion device 401 (n+3) starts. Also, the FD node 407 (n+2, n+3) is in a reset state at this time.

At point-in-time t21, the signal RES (n, n+1) goes to low level, and the signal SEL (n, n+1) goes to high level. The select transistor 405 (n, n+1) outputs at this time a first signal based on the potential of the FD node 407 (n, n+1) which the amplification transistor 404 (n, n+1) outputs, to the signal line 406 (m). The first signal is based on the potential at the time of resetting the FD node 407 (n, n+1), and includes noise from the resetting.

At point-in-time t22, the signal TX (n) goes to high level, and the charge which had been stored in the photoelectric conversion device 401 (n) is transferred. The select transistor 405 (n, n+1) outputs at this time a second signal based on the potential of the FD node 407 (n, n+1) which the amplification transistor 404 (n, n+1) outputs, to the signal line 406 (m). The second signal is a signal including an image signal based on the stored charge of the R pixel, and the aforementioned first signal.

Next, at point-in-time t23 the signal SEL (n, n+1) goes to low level, and the signal RES (n, n+1) goes to high level. The reset transistor 403 (n, n+1) resets the signal of the photoelectric conversion device 401 (n) of the FD node 407 (n, n+1) at this time.

At point-in-time t24, the signal RES (n+2, n+3) goes to low level, and the signal SEL (n+2, n+3) goes to high level. The select transistor 405 (n+2, n+3) outputs at this time a third signal based on the potential of the FD node 407 (n+2, n+3) to the signal line 406 (m). The third signal is based on the potential at the time of resetting the FD node 407 (n+2, n+3), and includes noise from the resetting.

At point-in-time t25, the signal TX (n+2) goes to high level, and the charge which had been stored in the photoelectric conversion device 401 (n+2) is transferred. The select transistor 405 (n+2, n+3) outputs at this time a fourth signal based on the potential of the FD node 407 (n+2, n+3) to the signal line 406 (m). The fourth signal is a signal including an image signal based on the stored charge of the G pixel, and the aforementioned third signal.

Next, at point-in-time t26 the signal SEL (n+2, n+3) goes to low level, and the signal RES (n+2, n+3) goes to high level. The reset transistor 403 (n+2, n+3) resets the signal of the photoelectric conversion device 401 (n+2) of the FD node 407 (n+2, n+3) at this time.

Signals of visible-light pixels are read out in order from row n+4, from this point-in-time t26 through point-in-time t31, in the same manner as with the readout of row n and row n+2 described above. One frame of signals based on visible light and infrared light is output during the period of point-in-time t11 through point-in-time t31.

Thereafter, at point-in-time t31, the signal RES (n, n+1) goes to low level, and the signal SEL (n, n+1) goes to high level. The select transistor 405 (n, n+1) outputs at this time a fifth signal based on the potential of the FD node 407 (n, n+1) to the signal line 406 (m). The fifth signal is based on the potential at the time of resetting the FD node 407 (n, n+1), and includes noise from the resetting.

At point-in-time t32, the signal TX (n+1) goes to high level, and the charge which had been stored in the photoelectric conversion device 401 (n+1) is transferred. The select transistor 405 (n, n+1) outputs at this time a sixth signal based on the potential of the FD node 407 (n, n+1) to the signal line 406 (m). The sixth signal is a signal including an image signal based on the stored charge of the IR pixel, and the aforementioned fifth signal.

Next, at point-in-time t33 the signal SEL (n, n+1) goes to low level, and the signal RES (n, n+1) goes to high level. The reset transistor 403 (n, n+1) resets the signal of the photoelectric conversion device 401 (n+1) of the FD node 407 (n, n+1) at this time.

At point-in-time t34, the signal RES (n+2, n+3) goes to low level, and the signal SEL (n+2, n+3) goes to high level. The select transistor 405 (n+2, n+3) outputs at this time a seventh signal based on the potential of the FD node 407 (n+2, n+3) to the signal line 406 (m). The seventh signal is based on the potential at the time of resetting the FD node 407 (n+2, n+3), and includes noise from the resetting.

At point-in-time t35, the signal TX (n+3) goes to high level, and the charge which had been stored in the photoelectric conversion device 401 (n+3) is transferred. The select transistor 405 (n+2, n+3) outputs at this time an eighth signal based on the potential of the FD node 407 (n+2, n+3) to the signal line 406 (m). The eighth signal is a signal including an image signal based on the stored charge of the IR pixel, and the aforementioned seventh signal.

Next, at point-in-time t35 the signal SEL (n+2, n+3) goes to low level, and the signal RES (n+2, n+3) goes to high level. The reset transistor 403 (n+2, n+3) resets the signal of the photoelectric conversion device 401 (n+3) of the FD node 407 (n+2, n+3) at this time.

Signals of IR pixels are read out in order from row n+5, from this point-in-time t36 through point-in-time t41, in the same manner as with the readout of row n+1 and row n+3 described above. The second frame of image signals based on infrared light is output during the period of point-in-time t31 through point-in-time t41. In the case of a moving image, the operations of points-in-time t11 through t41 are repeated after this point-in-time t41.

This readout method enables image signals based on visible light and image signals based on infrared light to be read out separately, facilitating signal processing. Also, the signal storage time of the photoelectric conversion devices at the IR pixels can be made to be longer than the signal storage time of the photoelectric conversion devices at the visible-light pixels. Accordingly, sensitivity to infrared light can be improved, and image signals based on sufficient infrared light can be acquired.

Next, signal processing will be described. A unit cell 201 illustrated in FIG. 2, for example, may be taken as a single pixel signal with regard to image signals based on the infrared light that has been read out. That is to say, the signals of the twelve IR pixels included in the unit cell 201 can be added. This sort of image signal processing can further improve sensitivity of image signals based on infrared light. This addition of image signals is performed after having output image signals to the signal line. However, a method of adding signal charges can be performed at the FD nodes. For example, a switch may be provided to connect the FD node 407 (n, n+1) and FD node 407 (n+2, n+3) in FIG. 8.

Also, in a case where improved sensitivity of infrared light is a priority, and arrangement may be made as another image signal processing method where resolution of infrared light is reduced and IR pixel signals are added. On the other hand, in a case where resolution of visible light is a priority, the IR pixels may be compensated by visible-light pixels around the IR pixels. Further, an arrangement may be made where the imaging apparatus switches between these images and alternately displays on a monitor, so that the user can recognize a high-resolution image and a high-sensitivity image.

Also, image signals that have been read out can be processed as follows. For example information of visible light at an IR pixel may be generated by compensation from color information and luminescence information at surrounding visible-light pixels. Specifically, information of an R pixel (m, n), a G pixel (m+2, n), a G pixel (m, n+2), and a B pixel (m+2, n+2), may be used for an IR pixel (m+1, n+1). The filter array in FIG. 2 enables such image signal processing.

Also, infrared light information at a visible-light pixel may be generated by compensation from information of the surrounding IR pixels. Specifically, information of an IR pixel (m+1, n+2), an IR pixel (m+2, n+1), an IR pixel (m+2, n+3), and an IR pixel (m+3, n+2), may be used for a B pixel (m+2, n+2). Further, an IR pixel (m+1, n+1), an IR pixel (m+1, n+3), an IR pixel (m+3, n+1), and an IR pixel (m+3, n+3), may be added. The filter array in FIG. 2 enables such image signal processing.

Further, the pitch of visible-light pixels is equidistant, and more specifically an R filter, B filter, and G filter are provided every other pixel as illustrated in FIG. 2. When looking at the visible-light pixels alone, this filter array is a normal Bayer array. Accordingly, a visible-light image can be formed using a signal processing unit according to the related art.

The photoelectric conversion device according to the present embodiment can be manufactured by commonly-available semiconductor technology. Specifically, a device may be formed on a semiconductor substrate by techniques according to the related art, such as photolithography, etching, ion injection, film formation, and so forth, and a filter having the above-described array formed above the semiconductor substrate. Alternatively, a filter array formed separately may be disposed on the semiconductor substrate upon which the device has been formed. The filters or filter array may also be manufactured by commonly-available technology.

Description has been made regarding the present embodiment where the filter array is formed of square shapes. However, in actual practice, the filter array may be arranged so that multiple IP filters are in contact at the corners, or may be a single IP filter. In the case of the latter, A single IR filter is formed having multiple apertures, with respective visible-light filters situated at the multiple apertures.

In this case, the shapes of the multiple apertures may be optional, such as circular or polygonal outline forms in plan view. A polygon has three or more corners. The filters may be in contact with each other, or may be overlapped at the edge portions of each other. In this case, the outer edge of each filter is determined by a plane which contacts with the adjacent filter and extends perpendicularly to the face of the semiconductor substrate. That is to say, in an arrangement where the edge of one filter having a circular shape in planar view is overlapping the edge of another such filter, if the boundary between the two such filters is defined by a plane which contacts with the adjacent filter and extends perpendicularly to the face of the semiconductor substrate, and such boundaries make up a polygonal shape in planar view as the outline of the filter, the outline of this filter can be said to have a polygonal shape.

Also, a light shielding member formed of metal or black organic material may be provided between the filters. It is sufficient for a light shielding member to be non-transparent as to light of visible-light wavelength. The light shielding member may include a black matrix. In this case, a light shielding member may be situated between multiple sides of one visible-light filter and one side of multiple IR filters, coming into contact with the multiple sides of the one visible-light filter and into contact with the one side of the multiple IR filters. The shielding member has multiple apertures, with an IR filter or visible-light filter situated at each of the multiple apertures. In this case, the shapes of the multiple apertures may be optional, such as circular or polygonal outline forms in plan view.

### Second Embodiment

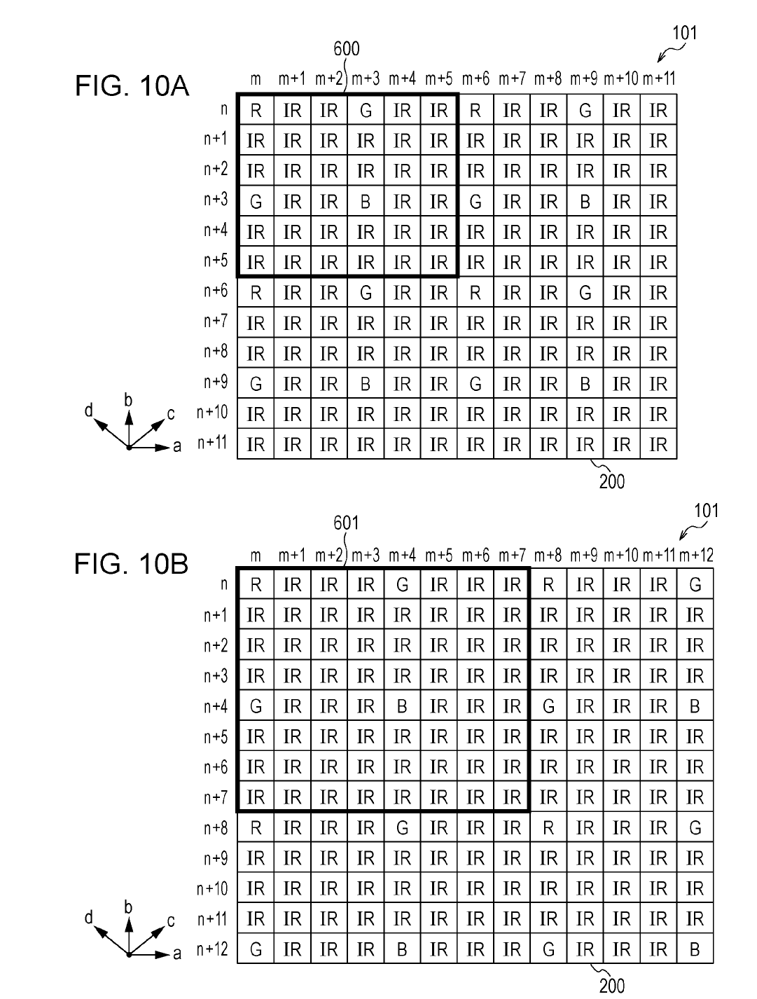

A photoelectric conversion device according to a second embodiment will be described with reference to FIGS. 10A and 10B, which illustrate filter arrays. The photoelectric conversion device according to the present embodiment differs from the first embodiment with regard to the array of visible-light filters. All other configurations are the same as with the first embodiment, so detailed description thereof will be omitted. FIGS. 10A and 10B are drawings corresponding to FIG. 2 of the first embodiment. Configurations which are the same as with the first embodiment are denoted by the same reference numerals, and description thereof will be omitted.

The visible-light filters in FIG. 2 are disposed every other pixel, and the unit cell 201 has a range including four pixels worth in the horizontal direction and four pixels worth in the vertical direction (4×4). On the other hand, the visible-light filters in FIG. 10A are disposed every two pixels in all of the row, column, and diagonal directions, and a unit cell 600 has a range including six pixels worth in the horizontal direction and six pixels worth in the vertical direction (6×6). Also, the visible-light filters in FIG. 10B are disposed every three pixels in all of the row, column, and diagonal directions, and a unit cell 601 has a range including eight pixels worth in the horizontal direction and eight pixels worth in the vertical direction (8×8).

The filter arrays in FIGS. 10A and 10B have a higher ratio of infrared light filters as compared to the filter array in the first embodiment, so sensitivity as to infrared light can be improved.

### Third Embodiment

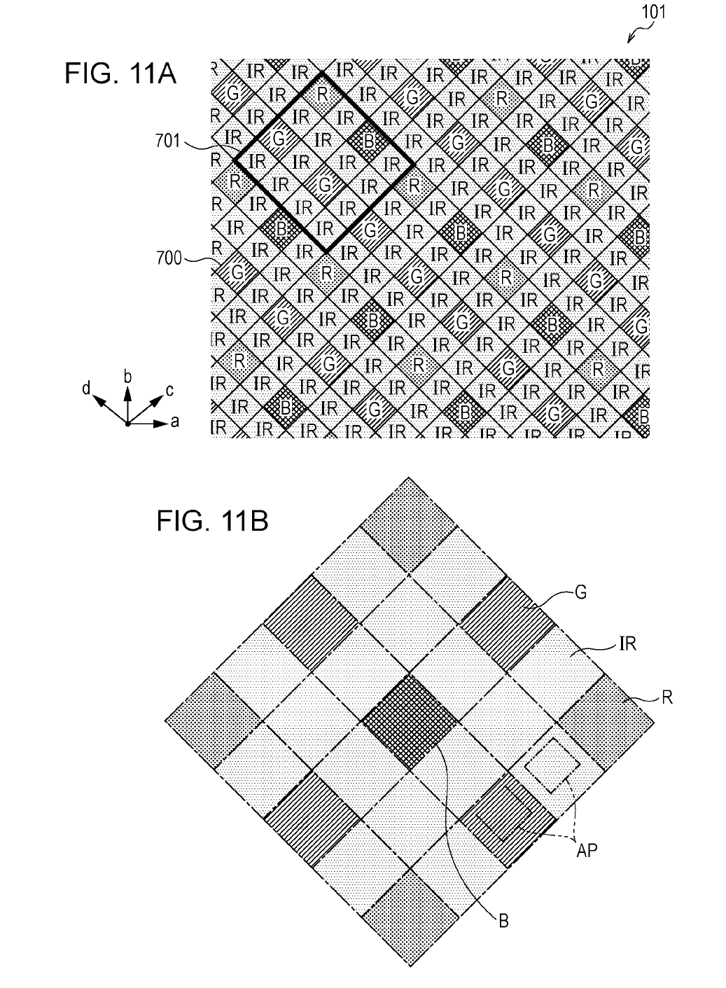

A photoelectric conversion device according to a third embodiment will be described with reference to FIGS. 11A and 11B, which illustrate filter arrays. The photoelectric conversion device according to the present embodiment differs from the first embodiment with regard to the array of pixels and the shape of pixels. All other configurations are the same as with the first embodiment, so detailed description thereof will be omitted. FIG. 11A is a drawing corresponding to FIG. 2 of the first embodiment. FIG. 11B is a drawing corresponding to FIG. 5 of the first embodiment. Configurations which are the same as with the first embodiment are denoted by the same reference numerals, and description thereof will be omitted. Note that the row and column numbers (n, m, and so forth) in FIG. 2 are omitted from FIG. 11A.

Pixels 700 in the pixel unit 101 illustrated in FIG. 11A have been rotated by 45 degrees as to the pixels 200 in FIG. 2. While the pixels are disposed in FIG. 2 so that the pixel rows follow the first direction a and the pixel columns follow the second direction b, the pixels are disposed in FIG. 11A so that the pixel rows follow the third direction c and the pixel columns follow the fourth direction d. FIG. 11B in an enlarged view of a part of the filter array illustrated in FIG. 11A. The filter array illustrated in FIG. 11B is of a configuration rotated by 45 degrees as to that illustrated in FIG. 5. The apertures AP formed corresponding to the filters are also rotated by 45 degrees as to those illustrated in FIG. 5, in the same way as with the filters.

IR filters are disposed between the visible-light filters in each of the row direction c, column direction d, and diagonal directions a and b, in the pixel array configuration according to the present embodiment. The filter array of visible-light pixel filters according to the present embodiment is not a Bayer array. Such a pixel array and filter array is also applicable, as long as IR pixels are provided around the visible-light pixels.

### Fourth Embodiment

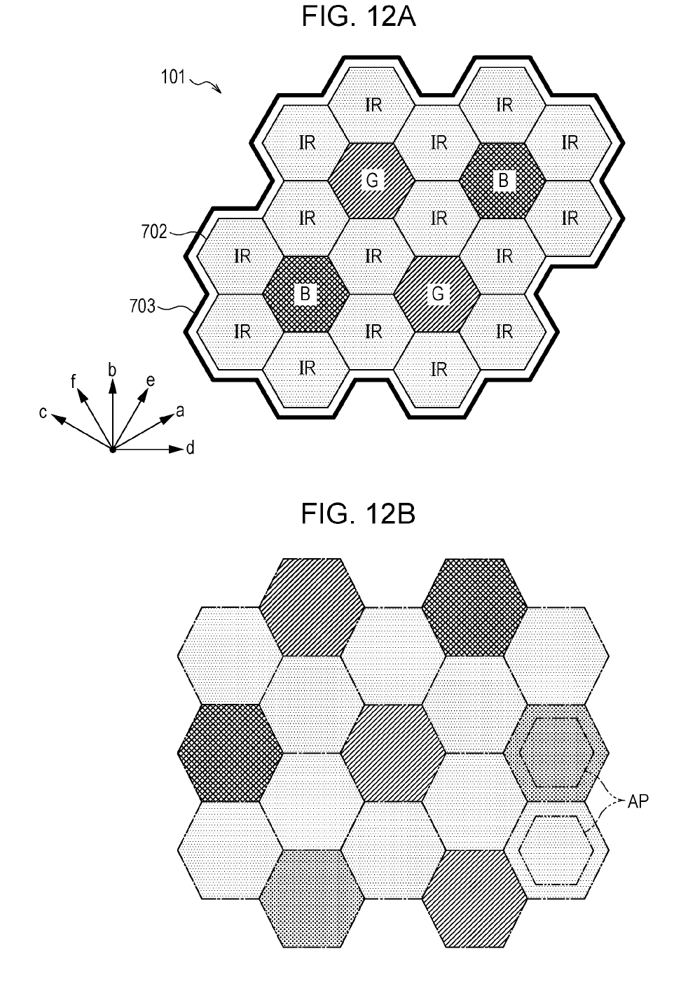

A photoelectric conversion device according to a fourth embodiment will be described with reference to FIGS. 12A and 12B, which illustrate filter arrays. The photoelectric conversion device according to the present embodiment differs from the first embodiment with regard to the array of pixels and the shape of pixels. All other configurations are the same as with the first embodiment, so detailed description thereof will be omitted. FIG. 12A is a drawing corresponding to FIG. 2 of the first embodiment. FIG. 12B is a drawing corresponding to FIG. 5 of the first embodiment. Configurations which are the same as with the first embodiment are denoted by the same reference numerals, and description thereof will be omitted.

Pixels 702 of the pixel unit 101 illustrated in FIG. 12A differ from the first embodiment in that the outline shape is a hexagon, while the pixels 200 illustrated in FIG. 2 are squares in their shape of outer edges. IR pixels are surrounding the visible-light pixels in the pixel array according to the present embodiment as well. Specifically, two IR pixels are disposed between each of the visible-light pixels in directions a, b, and c, which are directions perpendicular to one side of the visible-light pixels. Also, the corners of each visible-light pixel in the diagonal directions of the visible-light pixels, which are directions d, e, and f, come into contact with corners of IP pixels. A boundary region between IR pixels is situated between each of the visible-light pixels, so that the visible-light pixels do not come into contact with each other in the diagonal directions. Even such an arrangement where the array and shape of the visible-light pixels and IR pixels are different is applicable, as long as IR filters are provided next to the visible-light filters so as to surround the visible-light filters.

### Fifth Embodiment

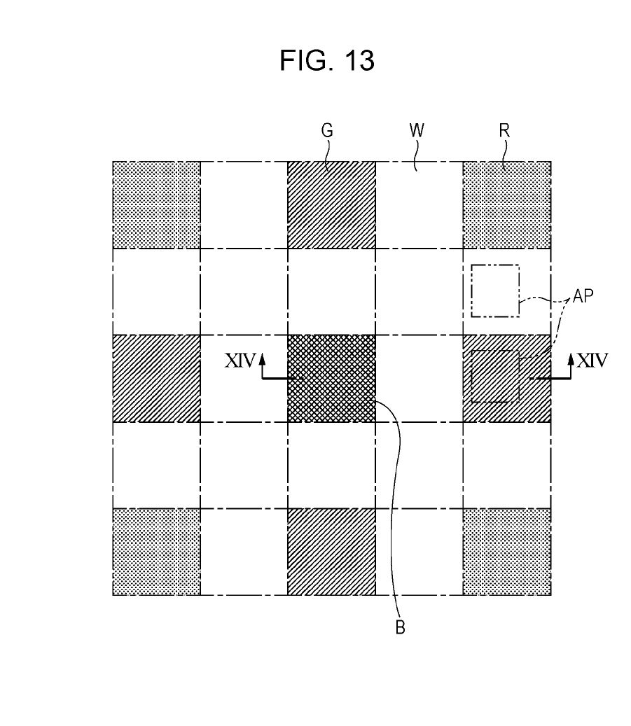

A photoelectric conversion device according to a fifth embodiment will be described with reference to FIG. 13. The photoelectric conversion device according to the present embodiment differs from the photoelectric conversion device according to the first embodiment with regard to the point that white-light filters (hereinafter referred to as W filters) are disposed instead of IR filters. While an IR filters selectively transmits near-infrared light, a W filter is not selective as to any wavelength of light transmitting through, and transmits light all wavelengths, including visible light and near-infrared light, in the same manner.

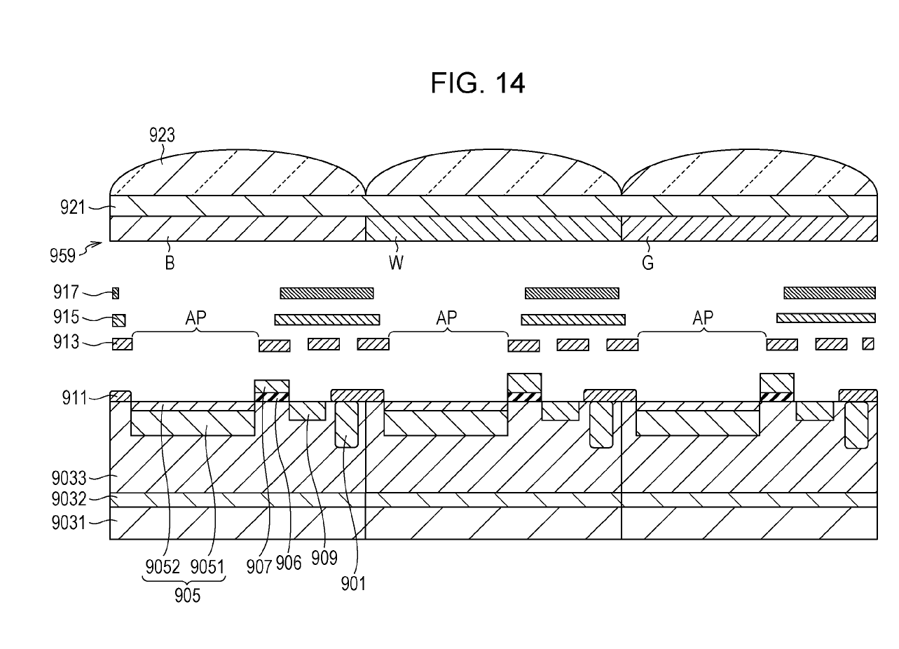

FIG. 14 is a cross-sectional view taken along XIV-XIV in FIG. 13. The configuration of a color filter 959 is the same as that in the first embodiment, other than that the IR filter has been replaced by the W filter. The W filters in the present embodiment are formed of the same material as microlenses 923, and is transparent. The W filters are formed so as to be in contact with adjacent B pixels, G pixels, and R pixels.

### Imaging Apparatus

An imaging apparatus in which the photoelectric conversion device has been included will be described exemplarily, as an application example of the photoelectric conversion device. The concept of the imaging apparatus is not restricted to cameras of which the primary purpose is to take photographs, and includes apparatuses of which photographing functions are supplemental (e.g., personal computers and portable terminals). The imaging apparatus includes the photoelectric conversion device exemplified in the embodiments described above, and a signal processing unit to process signals output from the photoelectric conversion device. The signal processing unit includes, for example, and A/D converter and a processor to process digital data output from this A/D converter, and can perform processing such as the addition described earlier.

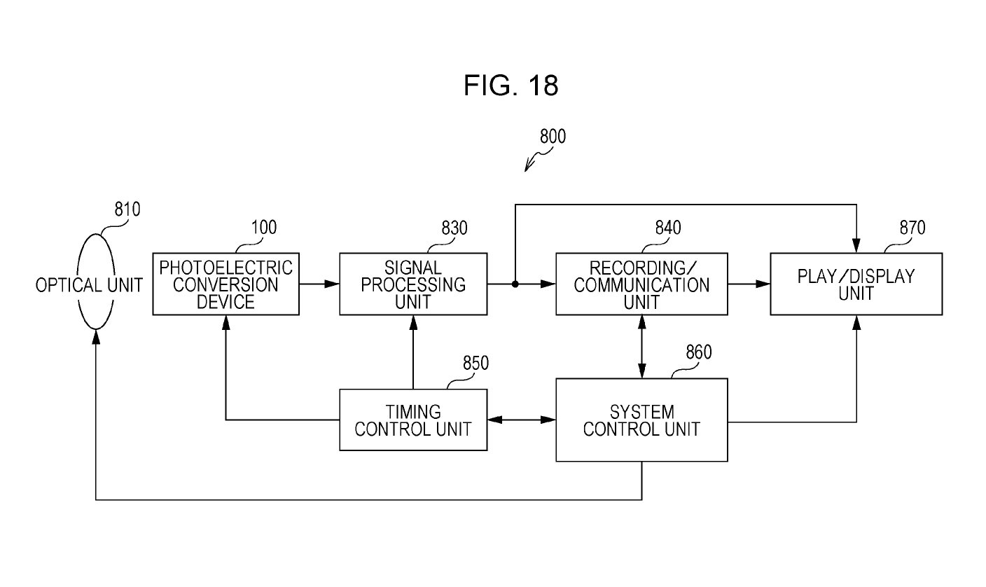

Now, an overview of a camera will be described with reference to FIG. 18, as an imaging apparatus 800. The imaging apparatus 800 includes, for example, an optical unit 810, the photoelectric conversion device 100, a signal processing unit 830, a recording/communication unit 840, a timing control unit 850, a system control unit 860, and a play/display unit 870. The timing control unit 850 and so forth may be formed integrally with the photoelectric conversion device 100.

The optical unit 810 which is an optical system formed of lenses and the like, images light from a subject on the pixel unit 101 of the photoelectric conversion device 100 illustrated in FIG. 1, and forms an image of the subject. The photoelectric conversion device 100 outputs signals according to light imaged on the pixel unit 101 in FIG. 1, based on signals from the timing control unit 850.

Signals output from the photoelectric conversion device 100 are input to the signal processing unit 830. The signal processing unit 830 performs processing on the input electric signals, such as A/D conversion and so forth, following a method stipulated by a program or the like. Signals obtained by the processing at the signal processing unit 830 are sent to the recording/communication unit 840 as image data. the recording/communication unit 840 sends signals for forming an image to the play/display unit 870. The play/display unit 870 plays moving images or displays still images. The recording/communication unit 840 may also communicate with the system control unit 860 or perform recording operations to record signals forming the image in an unshown recording medium, upon having received signals from the signal processing unit 830.

The system control unit 860 centrally controls operations of the imaging apparatus, and controls driving of the optical unit 810, timing control unit 850, recording/communication unit 840, and play/display unit 870. The system control unit 860 also includes an unshown storage device, which a recording medium for example, in which are recorded programs necessary for controlling the operations of the imaging apparatus. The system control unit 860 also supplies signals to switch driving modes according to user operations, for example, within the imaging apparatus. A specific example is changing of the readout method illustrated in the first embodiment, changing of angle of field in conjunction with electronic zooming, shifting angle of field in conjunction with electronic anti-deflection, and so forth. The timing control unit 850 controls the driving timing of the photoelectric conversion device 100 and signal processing unit 830 under control by the system control unit 860 serving as the control unit.

The imaging apparatus also includes medical imaging systems. For example, infrared light has permeability as to the living bodies. There is attention being given to a technology of visualizing living bodies by injecting a living body beforehand with an agent which is excited by infrared light and emits infrared fluorescence, and externally observing the living body by the fluorescence. There is demand in this field for detecting fluorescence from inside the body and also acquiring a visible image of the outside of the body at the same time. The embodiments enable fluorescence from the body to be detected and a visible image of the outside of the body to be acquired at the same time. This allows detection of fluorescence from inside the body shooting photographs of the body from the same direction, and can be applied to telemedicine, enlargement of images, and so forth.

### Signal Correction

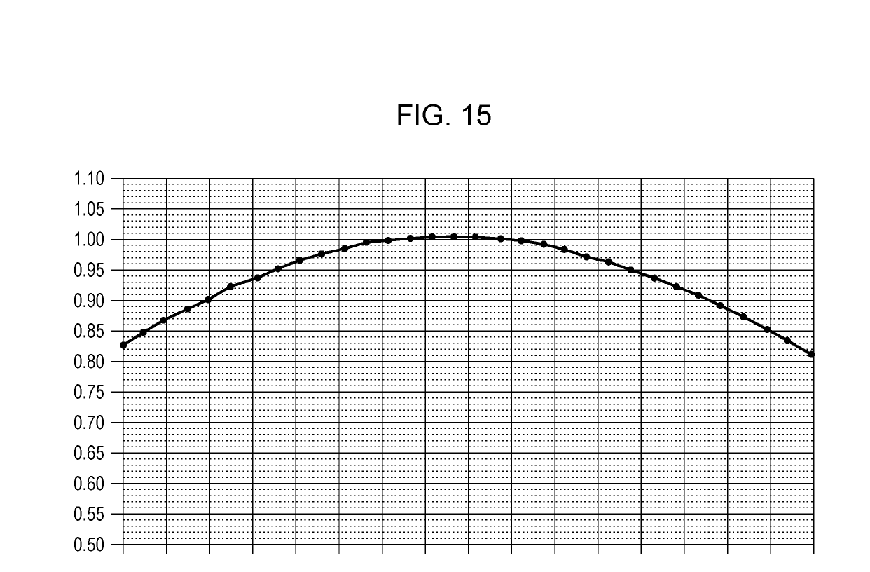

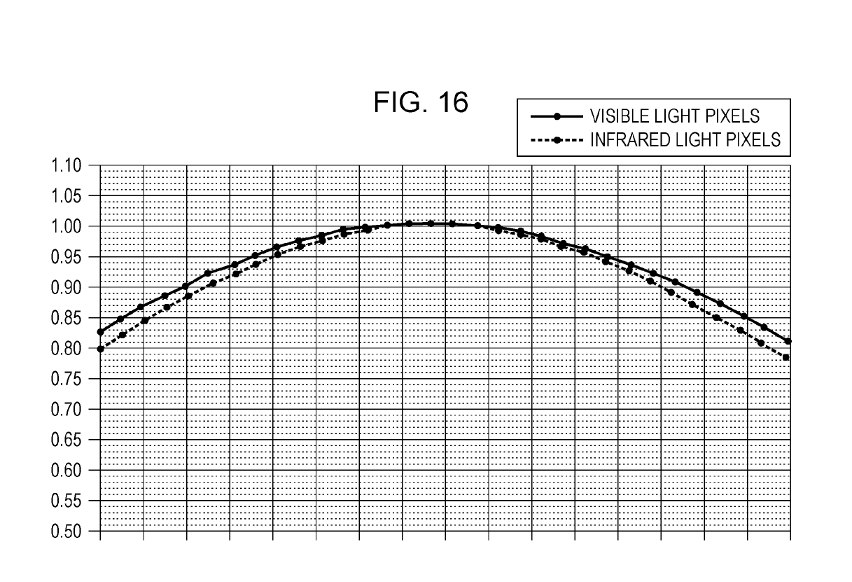

Next, signal correction performed at the signal processing unit 830 of the imaging apparatus described above will be described with reference to FIGS. 15 and 16.

Now, correction performed as to the signals detected at each pixel will be described with reference to FIG. 15. First, we will consider a case where light of a uniform amount is cast onto the entire region of the pixel unit 101 from the optical system disposed to the front of the photoelectric conversion device in the imaging apparatus. At this time, the amount of incident light to the pixels differs depending on the position thereof on the pixel unit 101. That is to say, light generally perpendicular to the light-receiving face of the pixels is input to pixels situated at the center of the pixel unit 101, but light tends to be input obliquely to the light-receiving face of the pixels situated at the perimeter of the pixel unit 101.

FIG. 15 illustrates difference in signals at each region on the pixel unit 101 at this time. FIG. 15 illustrates the amount of incident light to each pixel of a certain column in the row direction. The horizontal axis in FIG. 15 illustrates the positions along a certain row. Specifically, the left endpoint and the right endpoint on the horizontal axis indicate regions on the outermost perimeter of the pixel unit 101. The vertical axis indicates the amount of incident light to each region. The vertical axis represents the amount of incident light to the divided regions, with 1 being stipulated as the region with the greatest amount of light. The amount of incident light to the pixel unit 101 is normally greatest at the center of the pixel unit 101 and smaller away from the center of the pixel unit 101, as illustrated in FIG. 15. Accordingly, after light is input to the pixels and converted into electrical signals, these signals are corrected so as to complement the difference in amount of incident light depending on the position of the pixels. Specifically, the amplification values of light signals are decided so that the amount of light is 1 at all regions.

Now, IR light and visible light have different wavelengths, and the absorption depths thereof also differ. Accordingly, light with long wavelengths may, if input to the PD region 905 obliquely, pass through the PD region 905 obliquely and reach the p-type impurity region 901 or the like. Accordingly, correction corresponding to the wavelength of incident light to each pixels is also performed in conjunction with the imaging apparatus according to the present embodiment.

FIG. 16 is a diagram illustrating the amount of light signals at each region in the pixel unit 101 when infrared light and IR light are cast thereupon. The horizontal and vertical axes in FIG. 16 are the same as with FIG. 15. In FIG. 16, the solid line represents red light, and the dotted line indicates IR light. As illustrated in FIG. 16, the amount of IR light signals becomes particularly smaller than red light at the perimeter regions of the pixel unit 101. Correction of such difference in amount of incident light dependent on wavelengths is desirable to obtain more precise image information.

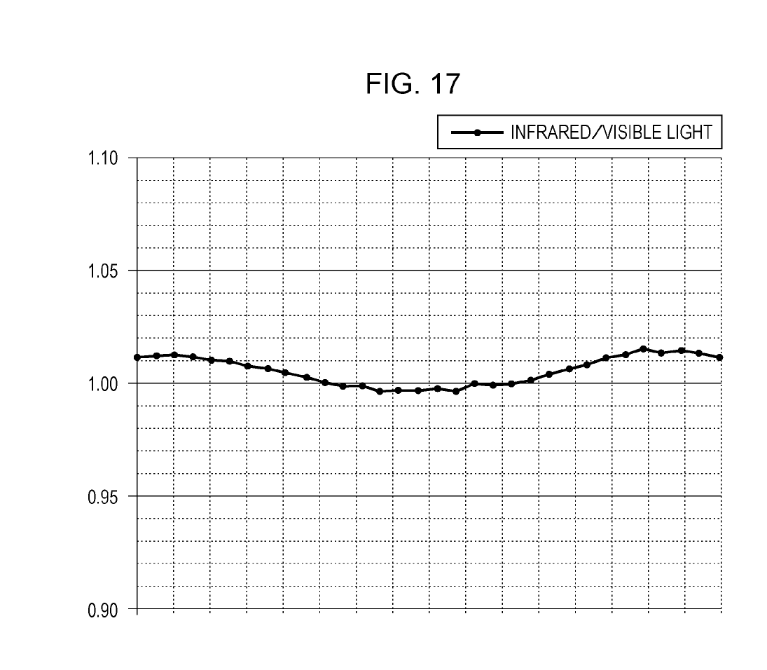

Correction of incident light amount dependent on light wavelength will be described with reference to FIG. 17. The horizontal axis in FIG. 17 is the same as with FIGS. 15 and 16. The vertical axis in FIG. 16 is a value obtained by dividing the intensity of red light signals by the intensity of IR light signals. That is to say, the vertical axis in FIG. 17 represents the ratio of red light signals as to IR light. The imaging apparatus according to the present embodiment corrects difference in incident light amount dependent on the position on the pixel unit 101 as illustrated in FIG. 15, and also corrects signals depending on the wavelength of light detected at each pixel. Note that while FIG. 17 illustrates only red light and IR light as an example of correction, the imaging apparatus according to the present invention also obtains and performs correction regarding the signal ratio regarding blue light and green light as well. That is to say, the signal ratios of red light, blue light, and green light, as to IR light, are obtained, and signal correction is performed at each pixel according to the wavelength of light detected thereat.

The embodiments may be modified or combined as suitable. For example, while the embodiments have been described using color filters of primary colors (red, green, blue), the invention is not restricted to these arrays, and these may be rearranged as suitable. Also, color filters of complementary colors may be used instead of the color filters of primary colors. Further, the planar shape of pixels is not restricted to rectangular shapes, nor restricted to having the same area; rather, pixels of any shape, such as triangles, hexagons, ellipses, and so forth, and of different shapes and areas, may be used. Moreover, the filters and pixels are not restricted to corresponding to each other in a one-on-one manner.

Also, apertures are described in the embodiments as being defined at positions corresponding to the photoelectric conversion regions by the first wiring layer 913 and second wiring layer 915, but may be defined by any on wiring layer of the first wiring layer 913, second wiring layer 915, and third wiring layer 917. Further, apertures may be defined by all three wiring layers.

Also, while description has been made in the embodiments using a front-side illumination CMOS photoelectric conversion device, the present invention is not restricted to a front-side illumination device; back-side illumination devices may be used, and various other types of photoelectric conversion devices such as CCDs or CMDs may be used.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-278323 filed Dec. 20, 2012 and No. 2013-243270 filed Nov. 25, 2013, which are hereby incorporated by reference herein in their entirety.

What is claimed is:

1. A photoelectric conversion device comprising:
a plurality of visible-light filters;
a plurality of infrared light filters;
a plurality of pixels arrayed in a row direction and a column direction; and
a plurality of wiring layers disposed between the plurality of pixels and the visible-light filters and infrared light filters;
wherein the plurality of pixels include first pixels disposed corresponding to the visible light filters, and second pixels disposed corresponding to the infrared light filters;
wherein the shape and size of the first pixels and the second pixels is the same in planar view;
wherein the second pixels are disposed between adjacent pixels of the plurality of first pixels in the row direction, the column direction, and diagonal directions;
wherein at least one wiring layer of the plurality of wiring layers defines apertures corresponding to photoelectric conversion regions at the first pixels and the second pixels; and
wherein apertures corresponding to the photoelectric conversion regions of the first pixels and apertures corresponding to the photoelectric conversion regions of the second pixels are of the same shape and size in planar view.

2. The photoelectric conversion device according to claim 1, wherein the outer edges of the visible-light filters and the outer edges of the infrared light filters form polygons with multiple sides, with the outer edges of the visible-light filters being in contact with one side or corner of one of the edges of the plurality of infrared light filters.

3. The photoelectric conversion device according to claim 1, the plurality of wiring layers further including
a first wiring layer disposed closest to the first pixels and the second pixels in a direction perpendicular to the light-receiving faces of the first pixels and the second pixels, and
a second wiring layer disposed further away from the first pixels and the second pixels in a direction perpendicular to the light-receiving faces of the first pixels and the second pixels as compared to the first wiring layer;
wherein the apertures are formed by the first wiring layer and the second wiring layer.

4. The photoelectric conversion device according to claim 1, wherein apertures corresponding to photoelectric conversion regions at the first pixels, and apertures corresponding to photoelectric conversion regions at the second pixels, are defined by two wiring layers of the plurality of wiring layers.

5. The photoelectric conversion device according to claim 1;
wherein the spectral transmittance of the visible-light filters is a value of 50% or greater in the wavelength range between 400 nm and 700 nm; and
wherein the spectral transmittance of the infrared light filters is a value less than 50% at lower than 700 nm, and a value of 50% or greater at a wavelength range of 700 nm or greater.

6. The photoelectric conversion device according to claim 1;
wherein the first pixels and the second pixels are arrayed in the row direction and the column direction; and
wherein at least two of the second pixels are disposed between each of the plurality of first pixels in the row direction and the column direction.

7. The photoelectric conversion device according to claim 1, wherein the visible light filters include infrared light cut-off filters.

8. An imaging apparatus, comprising:
the photoelectric conversion device according to claim 1; and
a signal processing unit configured to process signals of the photoelectric conversion device.

9. A photoelectric conversion device comprising:
a plurality of visible-light filters;
a plurality of white light filters;
a plurality of pixels arrayed in a row direction and a column direction; and
a plurality of wiring layers disposed between the plurality of pixels and the visible-light filters and white light filters;
wherein the plurality of pixels include first pixels disposed corresponding to the visible light filters, and second pixels disposed corresponding to the white light filters;
wherein the size and shape of the first pixels and the second pixels is the same;
wherein the second pixels are disposed between adjacent pixels of the plurality of first pixels in the row direction, the column direction, and diagonal directions;
wherein apertures are formed above the first pixels and the second pixels by the plurality of wiring layers; and
wherein the shape of the apertures are the same above the first pixels and above the second pixels.

10. The photoelectric conversion device according to claim 9, wherein the outer edges of the visible-light filters and the outer edges of the white light filters form polygons with multiple sides, with the outer edges of the visible-light filters being in contact with one side or corner of one of the edges of the plurality of white light filters.

11. The photoelectric conversion device according to claim 9, wherein the visible-light filters and white light filters are formed of an organic material, and are separated from each other.

12. The photoelectric conversion device according to claim 9, the plurality of wiring layers further including
a first wiring layer disposed closest to the first pixels and the second pixels in a direction perpendicular to the light-receiving faces of the first pixels and the second pixels, and
a second wiring layer disposed further away from the first pixels and the second pixels in a direction perpendicular to the light-receiving faces of the first pixels and the second pixels as compared to the first wiring layer;
wherein the apertures are formed by the first wiring layer and the second wiring layer.

13. The photoelectric conversion device according to claim 9, further comprising:
a plurality of microlenses disposed above the plurality of visible-light filters and plurality of white light filters;
wherein the white light filters are formed of the same material as the microlenses.

14. The photoelectric conversion device according to claim 9, wherein apertures corresponding to photoelectric conversion regions at the first pixels, and apertures corresponding to photoelectric conversion regions at the second pixels, are defined by two wiring layers of the plurality of wiring layers.

15. The photoelectric conversion device according to claim 9;
wherein the first pixels and the second pixels are arrayed in the row direction and the column direction; and
wherein at least two of the second pixels are disposed between each of the plurality of first pixels in the row direction and the column direction.

16. The photoelectric conversion device according to claim 9, wherein the visible light filters includes infrared light cut-off filters.

17. An imaging apparatus, comprising:
the photoelectric conversion device according to claim 9; and
a signal processing unit configured to process signals of the photoelectric conversion device.
